(19) United States
(12) Patent Application Publication
(10) Pub. No.: US 2010/0177573 A1
(43) Pub. Date: Jul. 15, 2010

(54) SEMICONDUCTOR MEMORY DEVICE AND SEMICONDUCTOR MEMORY DEVICE DRIVING METHOD

(75) Inventors: Fumiyoshi MATSUOKA, Kawasaki-Shi (JP); Katsuyuki FUJITA, Yokohama-shi (JP); Ryo FUKUDA, Yokohama-Shi (JP); Takashi OHSAWA, Yokohama-Shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/684,674

(22) Filed: Jan. 8, 2010

(30) Foreign Application Priority Data
Jan. 9, 2009 (JP) 2009-3714

(51) Int. Cl. G11C 7/10; G11C 7/00

(52) U.S. Cl. 365/189.05; 365/189.011

(57) ABSTRACT

A memory includes a latch circuit latching data from a first and a second bit lines to a first and a second sense nodes; a first data line reading-out the data from the first sense node to an outside; a second data line reading-out the data from the second sense node to the outside; a first write transistor connected between the first bit line and the first or second data line without via the first and second sense node; and a second write transistor connected between the second bit line and the first or second data line without via the first and second sense node, wherein in a write operation, the first write transistor transmits the data from the first or second data line to the first bit line, or the second write transistor transmits the data from the first or second data line to the second bit line.

### CROSS-REFERENCE TO RELATED APPLICATION

This application is based upon and claims the benefit of priority from the prior Japanese Patent Applications No. 2009-3714, filed on Jan. 9, 2009, the entire contents of which are incorporated herein by reference.

### BACKGROUND OF THE INVENTION

1. Field of the Invention

The present invention relates to a semiconductor memory device and a semiconductor memory device driving method, for example, to a FBC (Floating Body Cell) memory storing data by accumulating carriers in a floating body of a Field Effect Transistor.

2. Related Art

In recent years, there are FBC memory devices as a semiconductor memory device expected to replace 1T (Transistor)-1C (Capacitor) DRAMs. The FBC memory device is configured so that each of FETs (Field Effect Transistors) including a floating body (hereinafter, also “body”) is formed on an SOI (Silicon On Insulator) substrate and stores data “1” or “0” therein depending on the number of majority carriers accumulated in this body. It is defined that a state in which the number of holes (majority carriers) in the body is small is data “0” and that a state in which the number of holes in the body is large is data “1”.

Conventionally, in a data write operation, each sense amplifier temporarily detects data in each memory cell, overwrites the detected data with write data from outside, and then writes this write data to the memory cell. Therefore, in a conventional FBC memory device, the data write operation is always performed via a sense node of the sense amplifier. A feedback circuit included in the sense amplifier writes data latched to the sense node to each memory cell.

However, such a conventional data write technique has the following problems. Since a data detection operation and an operation for writing data to the sense amplifier are present, it is necessary to secure a rather long data write cycle time although a period of actually writing data to each memory cell is not so long. Accordingly, the rate of a substantial data write operation period in the data write cycle time is low. That is, conventional FBC memory devices disadvantageously require a long data write operation period (a long data write cycle).

### SUMMARY OF THE INVENTION

A semiconductor memory device according to an embodiment of the present invention comprises: a plurality of memory cells including bodies in electrically floating states, and configured to store data therein according to number of carriers in the bodies; a word line connected to gates of the memory cells; a first bit line and a second bit line configured to transmit data to the memory cells or to transmit the data from the memory cells; a first sense node and a second sense node connected to the first bit line and the second bit line, respectively; a latch circuit configured to latch the data from the first bit line to the first sense node, and to latch the data from the second bit line to the second sense node; a first data line configured to read the data latched to the first sense node to an outside or to transmit data from the outside to the first sense node; a second data line configured to read the data latched to the second sense node to the outside or to transmit the data from the outside to the second sense node; a first write transistor connected between the first bit line and the first data line or the second data line without via the first sense node and the second sense node; and a second write transistor connected between the second bit line and the first data line or the second data line without via the first sense node and the second sense node, wherein

in a data write operation, the first write transistor transmits the data from the first data line or the second data line to the first bit line, or the second write transistor transmits the data from the first data line or the second data line to the second bit line.

A method of driving a semiconductor memory device according to an embodiment of the present invention, the device comprising a plurality of memory cells configured to store data therein; a word line connected to gates of the memory cells; a first bit line and a second bit line configured to transmit the data from the memory cells; a first sense node and a second sense node corresponding to the first bit line and the second bit line, respectively; a first data line and a second data line corresponding to the first sense node and the second sense node, respectively; a first write transistor provided between the first bit line and the first data line or the second data line; and a second write transistor provided between the second bit line and the first data line or the second data line, the method comprising:

in a data write operation, causing the first write transistor to transmit data from the first data line or the second data line to the first bit line, or causing the second write transistor to transmit the data from the first data line or the second data line to the second bit line.

### BRIEF DESCRIPTION OF THE DRAWINGS

FIG. 1 is a circuit diagram showing a configuration of an FBC memory device according to a first embodiment of the present invention;

FIG. 2 is a cross-sectional view of an FBC;

FIG. 3 is a circuit diagram showing a configuration of one sense amplifier S/A, one write circuit WC and peripherals according to the first embodiment;

FIG. 4 is a timing chart showing a data write cycle of the FBC memory device according to the first embodiment;

FIG. 5 is a circuit diagram showing a configuration of each of sense amplifiers S/A according to a modification of the first embodiment;

FIG. 6 is a circuit diagram showing a configuration of each of sense amplifiers S/A in an FBC memory device according to a second embodiment of the present invention;

FIG. 7 is a timing chart showing a data write operation performed by the FBC memory device according to the second embodiment;

FIG. 8 is a timing chart showing a data write cycle of an FBC memory device according to a modification of the second embodiment;

FIG. 9 is a circuit diagram showing a configuration of each of sense amplifiers S/A in an FBC memory device according to a third embodiment of the present invention; and

FIG. 10 is a configuration diagram showing a generation circuit generating the write column selection signal bWCSL.

### DETAILED DESCRIPTION OF THE INVENTION

Embodiments of the present invention will be explained below in detail with reference to the accompanying drawings. Note that the invention is not limited thereto.

### First Embodiment

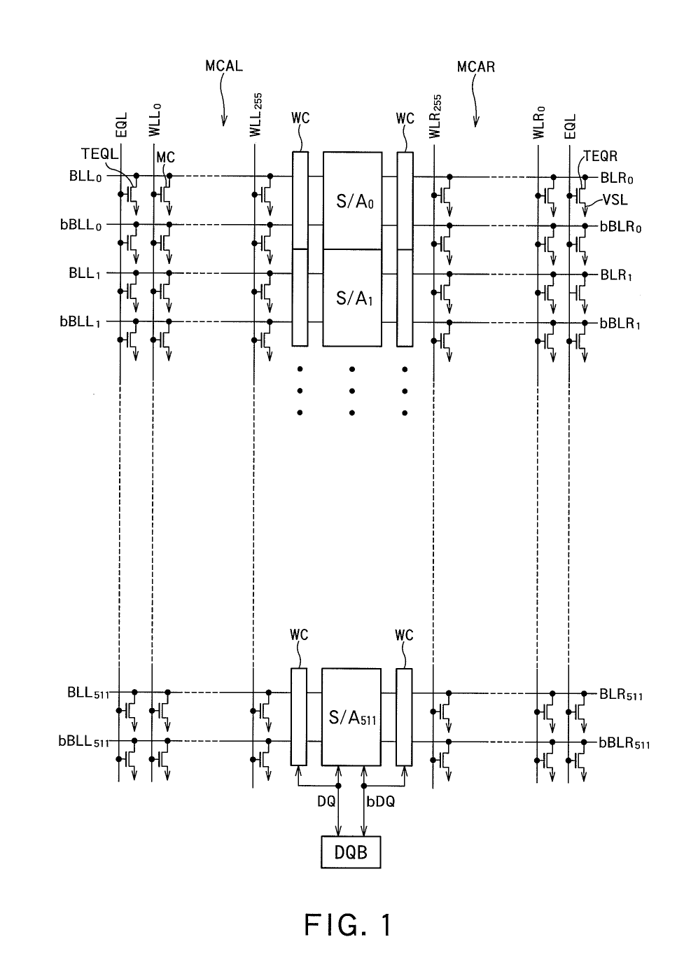

FIG. 1 is a circuit diagram showing a configuration of an FBC memory device according to a first embodiment of the present invention. The FBC memory device includes memory cells MC, sense amplifiers S/Ai (where i is an integer) (hereinafter, also “S/A”), word lines WLLi and WLRi (hereinafter, also “WLL” and “WLR” or “WL”), bit lines BLLi and BLRi (hereinafter, also “BLL” and “BLR” or “BL”), bit lines bBLLi and bBLRi (hereinafter, also “bBLL” and “bBLR” or “bBL”), equalizing lines EQL, and equalizing transistors TEQL and TEQR (hereinafter, also “TEQ”).

The FBC memory device according to the first embodiment has a two-cell-per-bit (2 cell/bit) architecture. The 2 cell/bit architecture is a method in which data of reverse polarities are written to two memory cells MC adjacent to each other on one word line WL and connected to paired bit lines BLL and bBLL or BLR and bBLR, respectively, thereby storing one-bit data. The data of reverse polarities means data complementary to each other such as data “0” and data “1”. To read data, one of the data of reverse polarities is referred to for the other data and the other data is referred to for one data. Accordingly, the paired bit lines BLL and bBLL or BLR and bBLR transmit the data of reverse polarities, respectively. In the first embodiment, it is defined that the bit line BLL or BLR is a first bit line and that the bit line bBLL or bBLR is a second bit line.

The memory cells MC are arranged in a matrix and constitute memory cell arrays MCAL and MCAR (hereinafter, also “MCA”). The word lines WLL and WLR extend in a row direction and are connected to gates of the memory cells MC. In the first embodiment, 256 word lines WLL and 256 word lines WLR are provided on the left and right of the sense amplifiers S/A, respectively (as WLL0 to WLL255 and WLR0 to WLR255). The bit lines BLL and BLR extend in a column direction and connected to sources or drains of the memory cells MC. 512 bit lines BLL and 512 bit lines BLR are provided on the left and right of the sense amplifiers S/A, respectively (as BLL0 to BLL511 and BLR0 to BLR511). The word lines WL are orthogonal to the bit lines BL and the memory cells MC are provided at intersecting points therebetween, respectively. The row direction and the column direction can be replaced with each other.

Each equalizing line EQL is connected to gates of the equalizing transistor TEQ. Each equalizing transistor TEQ is connected between one bit line BLL or BLR and a source potential VSL. In an equalizing operation, the bit lines BLL and BLR are connected to the source potential VSL, thereby making potentials of the bit lines BLL and BLR equal to each other.

Each sense amplifier S/A is connected to the bit lines BL and bBL and configured to detect data stored in each selected memory cell MC or to write data to each selected memory cell MC.

Write circuits WC are provided on both sides of each sense amplifier S/A, respectively. The write circuits WC are circuits that write data to the memory cells MC instead of or together with the corresponding sense amplifiers S/A. The write circuits WC will be described later in detail.

In a data read operation, data latched by one sense amplifier S/A is transmitted to a DQ buffer DQB via data lines DQ and bDQ. The data stored in the DQ buffer DQB is read to outside. In a data write operation, data from the outside is stored in the DQ buffer DQB. This data is transmitted to the write circuits WC and the sense amplifier S/A via the data lines DQ and bDQ.

Since a conventional DQ buffer can be used as the DQ buffer DQB, descriptions thereof will be omitted herein.

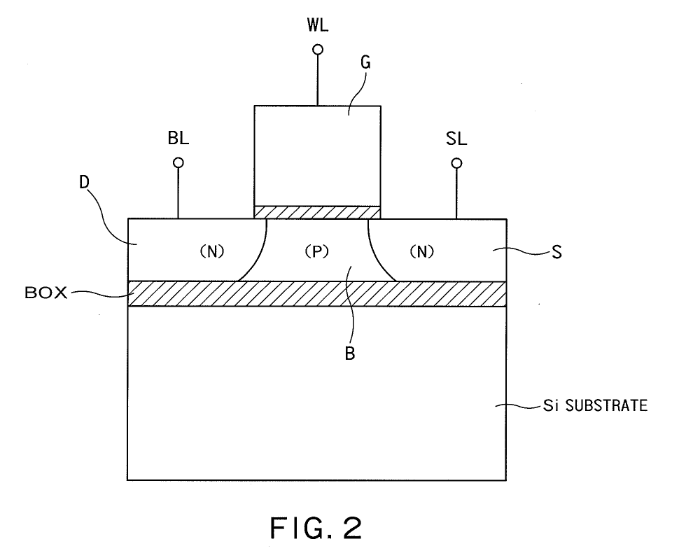

FIG. 2 is a cross-sectional view of an FBC (Floating Body Cell). In the FBC memory device, each FET including a floating body (hereinafter, also “body”) is formed on an SOI substrate and stores data “1” or data “0” therein according to the number of majority carries accumulated in the body. It is defined that a state in which the number of holes (majority carriers) in the body is small is data “0” and that a state in which the number of holes in the body is large is data “1”. Accordingly, if memory cells MC are N-FETs, the memory cells MC storing data “1” therein have a lower threshold voltage than that of the memory cells MC storing data “0” therein, and higher current is applied to the memory cells MC storing data “1” therein.

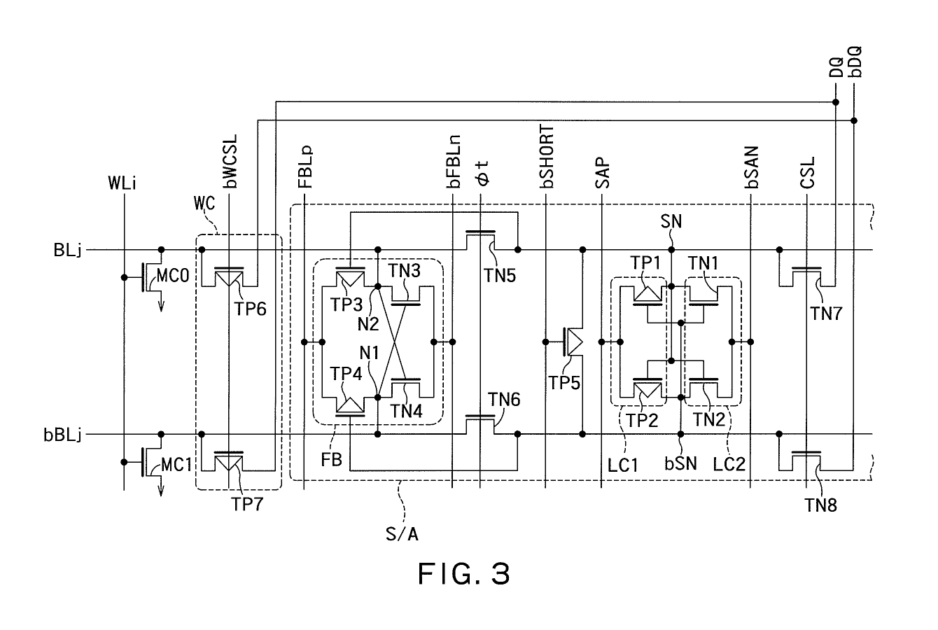

FIG. 3 is a circuit diagram showing a configuration of one sense amplifier S/A, one write circuit WC and peripherals according to the first embodiment. The sense amplifier S/A shown in FIG. 3 is structured to be connected to the bit lines BLL and bBLL on memory cell array MCAL side. Although the sense amplifier S/A is also connected to the bit lines BLR and bBLR on memory cell array MCAR side via transfer gates TN, respectively, the bit lines BLR and bBLR are not shown in FIG. 3. Furthermore, although another write circuit WC is provided on the memory cell array MCAR side, the write circuit WC is not shown in FIG. 3.

The paired bit lines BL and bBL are connected to sense nodes SN and bSN via transfer gates TN5 and TN6, respectively. The transfer gates TN5 and TN6 are controlled to be turned on or off by a signal ΦT. The NMOS transistors TN5 and TN6 can be replaced with PMOS or CMOS (Complementary MOS) transistors. The sense amplifier S/A includes the paired sense nodes SN and bSN. The sense amplifier S/A also includes latch circuits LC1 and LC2. The latch circuit LC1 is configured to include two p-transistors TP1 and TP2 connected in series between the sense nodes SN and bSN. A gate of the transistor TP1 is connected to the sense node bSN and a gate of the transistor TP2 is connected to the sense node SN. That is, the gates of the transistors TP1 and TP2 are cross-coupled to the sense nodes SN and bSN, respectively.

Likewise, gates of n-transistors TN1 and TN2 of the latch circuit LC2 are cross-coupled to the sense nodes SN and bSN, respectively. The latch circuits LC1 and LC2 are driven by signals SAP and bSAN, respectively. An n-transistor TN7 is connected between the data line DQ and the sense node SN. An n-transistor TN8 is connected between the data line bDQ and the sense node bSN. Gates of the transistors TN7 and TN8 are connected to a column selection line CSL. The column selection line CSL is selectively activated when data is read to the outside or written from the outside. In response to activation of the column selection line CSL, the sense nodes SN and bSN are connected to the DQ buffer DQB via the data lines DQ and bDQ, respectively. The data lines DQ and bDQ read the data latched by the sense nodes SN and bSN to the outside or transmit the data from the outside to the sense nodes SN and bSN, respectively.

The latch circuits LC1 and LC2 latch the data from the bit line BL to the sense node SN and latch the data from the bit line bBL to the sense node bSN. Further, the latch circuits LC1 and LC2 latch the data from the data line DQ to the sense node SN and latch the data from the data line bDQ to the sense node bSN.

Meanwhile, a feedback circuit FB is connected to the bit lines BL and bBL. The feedback circuit FB includes p-transistors TP3 and TP4 and n-transistors TN3 and TN4. The transistors TN3 and TP3 are connected in series between feedback signals FBLp and bFBLn. The transistors TN4 and TP4 are connected in series between the feedback signals FBLp and bFBLn.

A gate of the transistor TN3 as well as a connection node N1 between the transistors TN4 and TP4 is connected to the bit line bBL. A gate of the transistor TN4 as well as a connection node N2 between the transistors TN3 and TP3 is connected to the bit line BL. A gate of the transistor TP3 is connected to the sense node SN. A gate of the transistor TP4 is connected to the sense node bSN.

The feedback circuit FB is driven by the feedback signals FBLp and bFBLn. The feedback circuit FB applies potentials obtained by inverting and amplifying potentials of the sense nodes SN and bSN to the bit lines BL and bBL. That is, if the sense node SN is “H” level and the sense node bSN is “L” level, the feedback circuit FB applies the “L” level to the bit line BL and “H” level to the bit line bBL. If the sense node SN is “L” level and the sense node bSN is “H” level, the feedback circuit FB applies the “H” level to the bit line BL and “L” level to the bit line bBL.

The write circuit WC includes p-transistors TP6 and TP7. The transistor TP6 is connected between the data line bDQ and the bit line BL. The transistor TP7 is connected between the data line DQ and the bit line bBL. Gates of the transistors TP6 and TP7 are connected to a write column selection line bWCSL. The write column selection line bWCSL is a signal line selectively activated when data is written from the outside. When the write column selection line bWCSL is activated, the write circuit WC can directly connect the data lines bDQ and DQ to the bit lines BL and bBL without via the sense amplifier S/A, respectively.

A shorted transistor TP5 is controlled by a signal bSHORT. The shorted transistor TP5 keeps the sense nodes SN and bSN equal in potential in a data precharge operation, and disconnects the sense nodes SN and bSN from each other in the data read or write operation. In the first embodiment, the signal SAP is always active and the sense nodes SN and bSN are connected to a high-level voltage VBLH via the transistors TP1 and TP2.

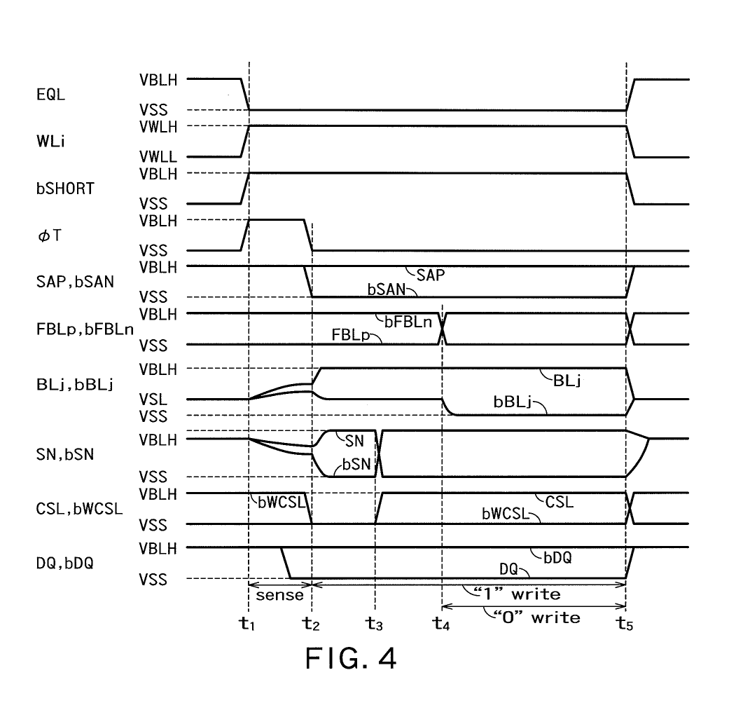

FIG. 4 is a timing chart showing a data write cycle of the FBC memory device according to the first embodiment. It is assumed that a memory cell MC0 included in the memory cell array MCAL shown in FIG. 3 initially stores data “0” therein and that a memory cell MC1 shown in FIG. 3 initially stores data “1” therein. It is also assumed that data “1” is written to the memory cell MC0 and that data “0” is written to the memory cell MC1. The sense amplifiers S/A in unselected columns restore detected data in unselected memory cells MC that are non-write targets among the memory cells MC connected to a selected word line WLi, in logical states as they are.

Since an operation in the memory cell array MCAR can be easily estimated from an operation in the memory cell array MCAL, the operation in the memory cell array MCAR is not described herein.

To write the data “0” to the memory cell MC1, holes accumulated in the body B are withdrawn to the bit line bBLj using a forward bias between the body B and a drain of the memory cell MC1. To write the data “1” to the memory cell MC0, a high-level voltage VWLH of the word line WLi and the high-level voltage VBLH of the bit line BLj cause impact ionization, thereby accumulating holes in the body B of the memory cell MC1

The data write cycle includes a data detection operation and a data write operation (or a data restore operation). A data write period does not include a data detection period but the data write period is a period in which data is written to each memory cell MC.

In a precharged state (before t1), the signals EQL and bSHORT are activated (active). The bit lines BL and bBL are fixed to an equal potential, accordingly. Further, the p-transistor TP5 keeps the sense node SN and bSN equal in potential.

Note that “to activate” means to turn on or drive an element or a circuit and that “to deactivate” means to turn off or stop the element or the circuit. Accordingly, a HIGH (high-potential level) signal is an activation signal on one occasion and a LOW (low-potential level) signal is an activation signal on another occasion. For example, an NMOS transistor is activated by setting a gate thereof HIGH. A PMOS transistor is activated by setting a gate thereof LOW.

At the t1, the signals EQL and bSHORT are deactivated. As a result, the bit line BL is disconnected from the bit line bBL and the sense node SN is disconnected from the sense node bSN. At the same time, a certain word line WLi (where i is an integer) is selectively activated. The other word lines WL are kept in a data retention state (VWLL). The signal ΦT is activated to high level. As a result, the bit lines BLj and bBLj (where j is an integer) are connected to the sense nodes SN and bSN, respectively.

The signal SAP is always active. Accordingly, the signal SAP drives the latch circuit LC1 to connect the high-level voltage VBLH to the sense nodes SN and bSN. A load current is applied to the memory cells MC0 and MC1 via the sense nodes SN and bSN and the bit lines BLj and bBLj. That is, the FBC memory device according to the first embodiment is configured so that the p-transistors TP1 and TP2 apply the load current (configured to employ a pMOS load). From the t1 to t2, a potential difference (signal difference) is generated between the sense nodes SN and bSN. At the time (the t2) when the signal difference is sufficiently large between the sense nodes SN and bSN, the signal ΦT is deactivated to low level and the sense nodes SN and bSN are disconnected from the bit lines BLj and bBLj, respectively.

From the t1 to the t2, write data from the outside is stored in the DQ buffer DQB. As a result, the data line DQ falls to be logically low. At the t2, the write column selection line bWCSL is activated almost simultaneously with deactivation of the signal ΦT. As a result, the data line DQ is connected to the bit line bBLj via the transistor TP7. In addition, the data line bDQ is connected to the bit line BLj via the transistor TP6. That is, the write transistor TP7 transmits the data from the data line DQ to the bit line bBLj without via the sense amplifier S/A. In addition, the write transistor TP6 transmits the data from the data line bDQ to the bit line BLj without via the sense amplifier S/A. However, it is easy for the write circuit WC to transmit the high-level potential VBLH but difficult for the write circuit WC to transmit a low-level potential VSS since the write circuit WC is configured to include the p-transistors TP6 and TP7. Due to this, in a period from the t2 to t4, the bit line BLj rises to VBLH but the bit line bBLj does not sometimes fall sufficiently to VSS.

At t3, the column selection line CSL is activated. The data lines DQ and bDQ corresponding to the selected column are connected to the sense nodes SN and bSN, respectively. Logics of the sense nodes SN and bSN are thereby inverted. This means that the write data is transmitted from the data lines DQ and bDQ to the sense nodes SN and bSN, respectively. The latch circuits LC1 and LC2 latch the write data to the sense nodes SN and bSN, respectively.

At the t4, the feedback circuit FB is activated. The feedback signals FBLp and bFBLn are thereby made logically high and logically low, respectively. The feedback circuit FB thereby transmits the write data latched to the sense nodes SN and bSN to the bit lines bBLj and BLj, respectively. At this time, the bit line bBLj can fall sufficiently to the low-level potential VSS. At t5, the data write cycle ends and the FBC memory device turns into the precharged state.

In this way, in the first embodiment, the write circuit WC directly transmits the write data from the data lines DQ and bDQ to the bit lines bBLj and BLj via the sense amplifier S/A (sense nodes SN and bSN), respectively. From the t2 to the t5, the data “1” is thereby written to the memory cell MC0. It is to be noted that the operation for writing the data “0” to the memory cell MC1 is executed substantially in a period from the t4 to the t5. As a result, in the first embodiment, if the data write cycle (t1 to t5) is constant, a data “1” write period can be made substantially longer than that according to the conventional technique. This follows that a rate of the data “1” write period in the data write cycle time is higher than that according to the conventional technique. On the other hand, if the data “1” write period is constant, the data write cycle time can be made substantially short. That is, it is possible to shorten the data write cycle time and the accelerate operation.

### Modification of First Embodiment

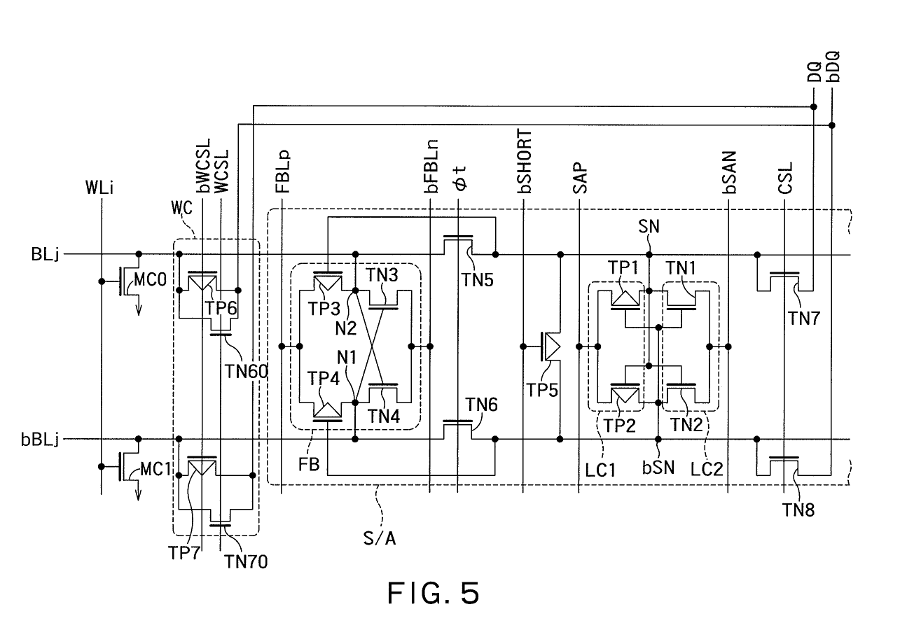

FIG. 5 is a circuit diagram showing a configuration of each of sense amplifiers S/A according to a modification of the first embodiment. In the first embodiment, the write circuit WC is configured to include the p-transistors TP6 and TP7. Alternatively, the write circuit WC can be configured to include CMOS (Complementary MOS) transistors. That is, a write circuit WC according to the modification includes the p-transistor TP6 and an n-transistor TN60 connected in parallel, and the p-transistor TP7 and an n-transistor TN70 connected in parallel. Gates of the transistors TN60 and TN70 are connected to a write column selection signal WCSL (an inverted signal with respect to a write column selection signal bWCSL).

In this case, the n-transistor TN60 or TN70 can directly transmit the low-level voltage VSS from the data line DQ or bDQ to the bit line bBLj or BLj. Due to this, right after the t2 shown in FIG. 4, the bit line bBLj falls to the low-level potential VSS. As a result, in this modification, not only the rate of the data “1” write period but also a rate of a data “0” write period are higher in the data write cycle time.

It is necessary to provide the feedback circuit FB to write back (restore) data latched by each of the sense amplifiers S/A in unselected columns that are non-write targets to the memory cells MC.

### Second Embodiment

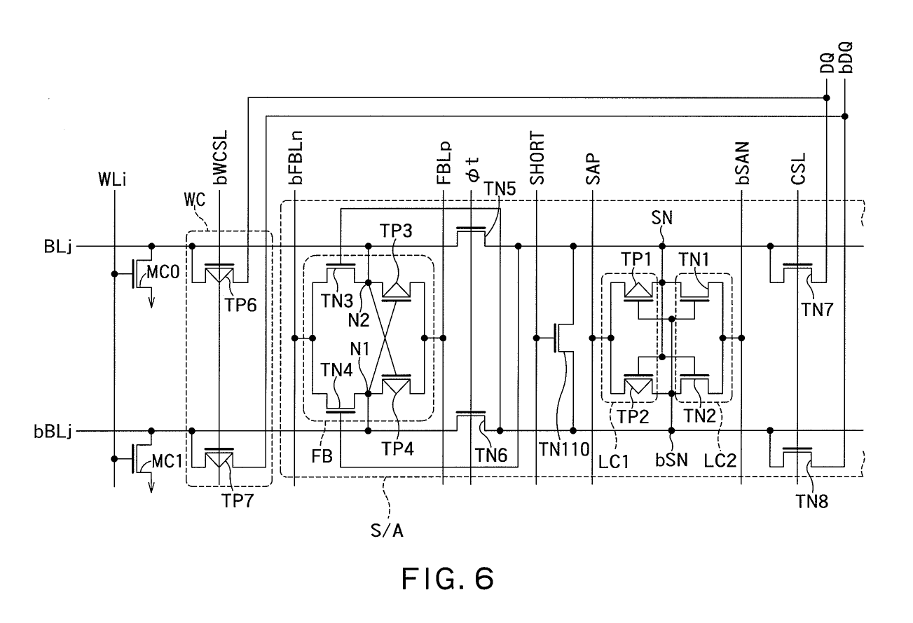

FIG. 6 is a circuit diagram showing a configuration of each of sense amplifiers S/A in an FBC memory device according to a second embodiment of the present invention. In the second embodiment, a signal bSAN is always active. The FBC memory device is configured so that n-transistors TN1 and TN2 apply a load current (configured to employ an nMOS load). In this case, a latch circuit LC2 applies (withdraws) the load current from each memory cell MC. A shorted transistor is an n-transistor TN110. The transistor TN110 is controlled by a signal SHORT (an inverted signal with respect to a signal bSHORT).

Furthermore, a transistor TP6 is connected between a data line DQ and a bit line BL since the FBC memory device employs the nMOS load. A transistor TP7 is connected between a data line bDQ and a bit line bBL.

The feedback circuit FB includes p-transistors TP3 and TP4 and n-transistors TN3 and TN4. The transistors TN3 and TP3 are connected in series between feedback signals FBLp and bFBLn. The transistors TN4 and TP4 are connected in series between the feedback signals FBLp and bFBLn.

A gate of the transistor TP3 as well as a connection node N1 between the transistors TN4 and TP4 is connected to the bit line bBL. A gate of the transistor TP4 as well as a connection node N2 between the transistors TN3 and TP3 is connected to the bit line BL. A gate of the transistor TN3 is connected to the sense node bSN. A gate of the transistor TN4 is connected to the sense node SN.

The feedback circuit FB is driven by the feedback signals FBLp and bFBLn. The feedback circuit FB applies potentials obtained by amplifying potentials of the sense nodes SN and bSN to the bit lines BL and bBL. That is, if the sense node SN is “H” level and the sense node bSN is “L” level, the feedback circuit FB applies the “H” level to the bit line BL and “L” level to the bit line bBL. If the sense node SN is “L” level and the sense node bSN is “H” level, the feedback circuit FB applies the “L” level to the bit line BL and “H” level to the bit line bBL. Other configurations of the second embodiment can be identical to those of the first embodiment.

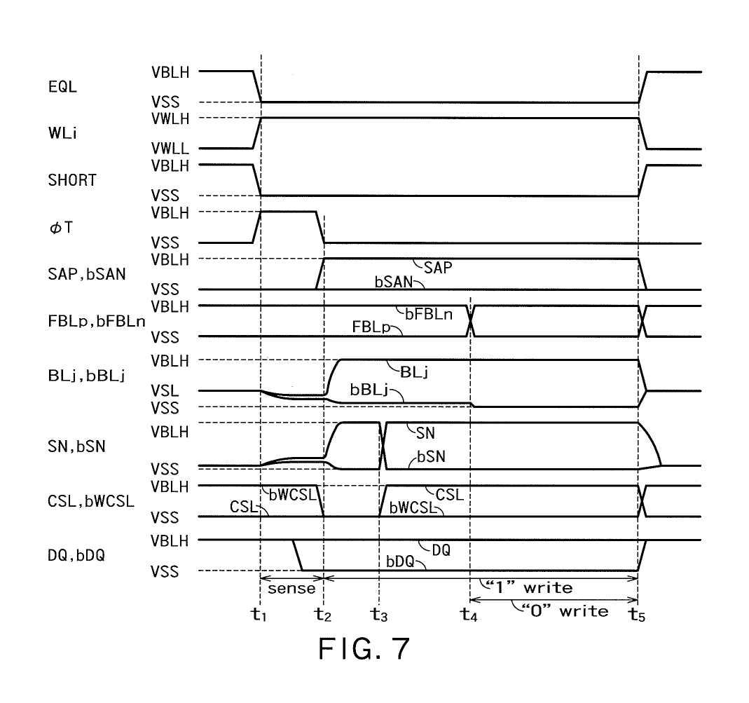

FIG. 7 is a timing chart showing a data write operation performed by the FBC memory device according to the second embodiment. In the second embodiment, the signal bSAN is always active. In a precharged state, the shorted transistor TN110 keeps sense nodes SN and bSN equal in potential. The bit lines BL and bBL are kept to VSL (>VSS). In a data detection period from t1 to t2, a latch circuit LC2 configured to include n-transistors TN1 and TN2 withdraws the load current from the memory cell MC. That is, the load current is applied from the memory cell MC to the latch circuit LC2. As a result, after voltages of the bit lines BLj and bBLj fall and those of the sense nodes SN and bSN rise, a signal difference between data “0” and data “1” increases. Operations after the t2 are identical to those after the t2 shown in FIG. 4.

The second embodiment can achieve effects identical to those of the first embodiment.

A write circuit WC according to the second embodiment can be configured to include CMOS transistors similarly to the modification of the first embodiment. Accordingly, the second embodiment can achieve effects identical to those of the modification of the first embodiment.

### Modification of Second Embodiment

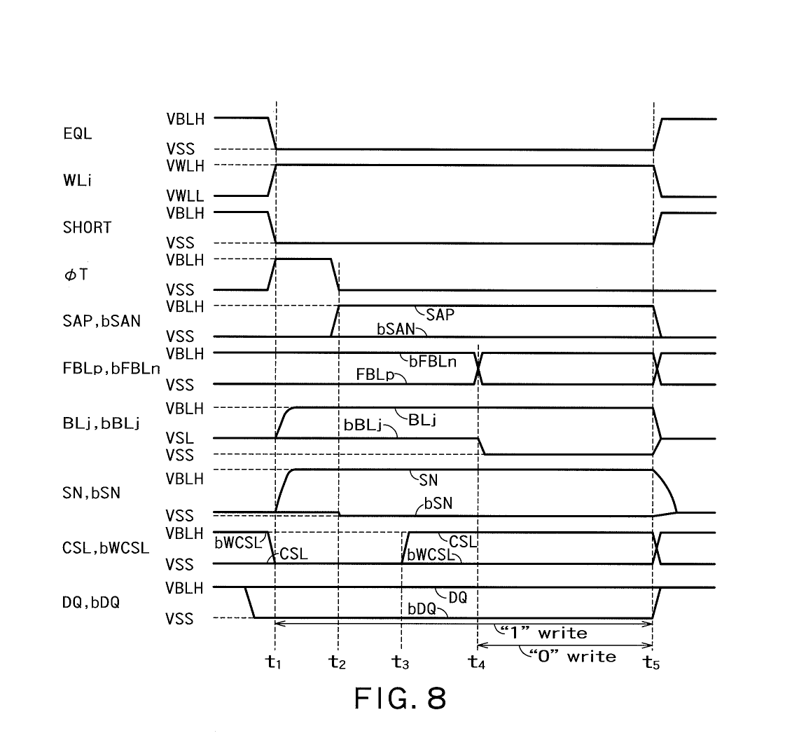

FIG. 8 is a timing chart showing a data write operation of an FBC memory device according to a modification of the second embodiment. In this modification, in a precharged state before t1, data lines DQ and bDQ already transmit write data from outside. At the t1, a write column selection signal bWCSL is activated and a write circuit WC connects the data lines DQ and bDQ to bit lines BLj and bBLj, respectively. Accordingly, at the t1, a data “1” write operation starts. Data detection is performed on memory cells MC in unselected columns that are non-write targets. Data stored in memory cells MC in a selected column that is a write target is substantially not detected. Operations at and after t2 according to this modification are identical as those according to the second embodiment.

In this way, in the modification of the second embodiment, a write transistor TP6 connects the bit line BL to the data line DQ and a write transistor TP7 connects the bit line bBL to the data bDQ almost simultaneously with a timing when sense amplifiers S/A start detecting data stored in unselected memory cells MC. It is thereby possible to further increase a rate of a data “1” write period in the data write cycle time. Alternatively, it is thereby possible to further shorten the data write cycle time.

The modification of the second embodiment can be applied to the first embodiment. That is, before the t1 shown in FIG. 4, the data lines DQ and bDQ can already transmit the write data from the outside. At the t1, the write column selection signal bWCSL can be activated and the write circuit WC can connect the data lines DQ and bDQ to the bit lines bBLj and BLj, respectively. In the first embodiment, it is thereby possible to further increase the rate of the data “1” write period in the data write cycle time. Alternatively, it is thereby possible to further shorten the data write cycle time.

In the configuration shown in FIG. 4, the PMOS load is employed. Due to this, the feedback circuit FB inverts potentials of the sense nodes SN and bSN and applies the inverted potentials to the bit lines BLj and bBLj, respectively. The data applied from the data lines bDQ and DQ to the bit lines BLj and bBLj via the write circuit WC is also transferred to the sense nodes SN and bSN from the t1 to t2 in FIG. 8. Due to this, at t4, before activation of the feedback circuit FB, it is necessary to activate a column selection line CSL. As a result, data opposite in logic to that of the data from the write circuit WC is written from the data lines DQ and bDQ to the sense nodes SN and bSN, respectively.

### Third Embodiment

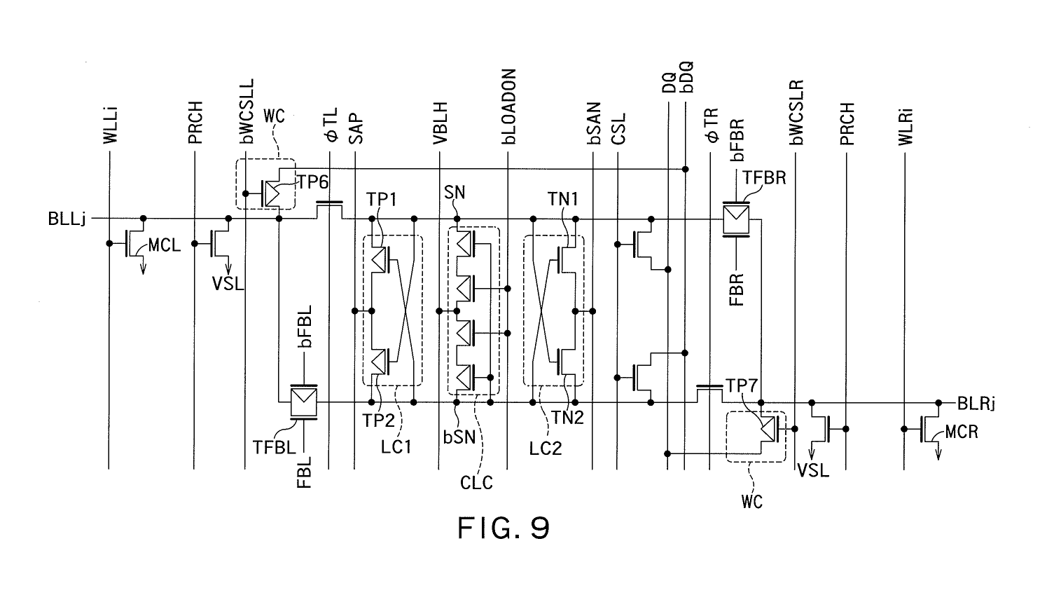

FIG. 9 is a circuit diagram showing a configuration of each of sense amplifiers S/A in an FBC memory device according to a third embodiment of the present invention. In the third embodiment, each sense amplifier S/A operates in a one-cell-per-bit (1 cell/bit) architecture. The 1 cell/bit architecture is a method in which one memory cell MC stores one-bit data therein. Each sense amplifier S/A detects the data stored in one data MC using reference data received from outside or reference data generated by a dummy cell (not shown).

Furthermore, the FBC memory device according to the third embodiment adopts an open-bit line configuration. Accordingly, each sense amplifier S/A is connected to bit lines BLLj and BLRj corresponding to memory cell arrays MCAL and MCAR arranged on both sides of the sense amplifier S/A, respectively. If detecting data stored in one memory cell MC connected to the bit line BLLj, the sense amplifier S/A receives the reference data from the bit line BLRj. Conversely, if detecting data stored in one memory cell MC connected to the bit line BLRj, the sense amplifier S/A receives the reference data from the bit line BLLj.

In the third embodiment, the sense amplifier S/A does not include a feedback circuit FB but includes instead a current-mirror-type current load circuit CLC between sense nodes SN and bSN. The current load circuit CLC connects a high-level voltage VBLH to the sense nodes SN and bSN via two p-transistors connected in series, and applies an equal voltage to the sense nodes SN and bSN when a signal bLOADON is activated to be logically low. The sense amplifier S/A can thereby apply a load current to the memory cell MC during a data detection operation.

In the third embodiment, a p-transistor TP6 is connected between the bit line BLLj and a data line bDQ. A p-transistor TP7 is connected between the bit line BLRj and a data line DQ. A write circuit WC can thereby directly connect the data lines DQ and bDQ to the bit lines BLRj and BLLj without via the sense amplifier S/A, respectively.

Write column selection lines bWCSLL and bWCSLR control the transistors TP6 and TP7, respectively. The write column selection lines bWCSLL and bWCSLR are driven similarly to the signal bWCSL shown in FIG. 4. The other signal lines in the third embodiment can operate similarly to an operation shown in FIG. 4. Accordingly, it is clear that the present invention is also applicable to a 1 cell/bit FBC memory device.

Alternatively, each write circuit WC can be configured to include CMOS transistors similarly to the modification of the first embodiment. That is, the write circuit WC can include a p-transistor TP6 and an n-transistor TN60 connected in parallel and a p-transistor TP7 and an n-transistor TN70 connected in parallel. Accordingly, the third embodiment can also achieve effects identical to those of the modification of the first embodiment.

The current load circuit CLC is configured to include p-transistors and connects the high-level voltage VBLH to the sense nodes SN and bSN. Alternatively, the current load circuit CLC can be configured to include n-transistors and connect a low-level voltage VSS to the sense nodes SN and bSN. In this alternative, the current load circuit CLC operates to withdraw current from the memory cell MC similarly to the second embodiment.

In addition, the third embodiment can be combined with the modification of the second embodiment. That is, write transistors TP6 and TP7 can be made conductive substantially simultaneously with a timing of starting detecting data in unselected memory cells MC. Thus, the third embodiment can also achieve effects identical to those of the modification of the second embodiment.

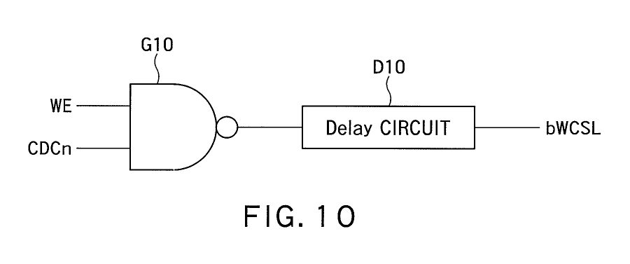

FIG. 10 is a configuration diagram showing a generation circuit generating the write column selection signal bWCSL. This generation circuit includes a NAND gate G10 and a delay circuit D10. A column decoder signal CDCn and a write enable signal WE are input to the NAND gate G10. An output from the NAND gate G10 is connected to the delay circuit D10. The delay circuit D10 delays an output signal from the NAND gate G10 by a predetermined period and outputs the delayed signal as the write column selection signal bWCSL.

The write enable signal WE is a signal activated to be logically high in the data write operation. Accordingly, the write enable signal WE is activated in a period from the t2 to t5 or from the t1 to the t5 shown in FIG. 4 and the like.

The column decoder signal CDCn is a signal activated to be logically high during column selection. The column decoder signal CDCn is activated before the t1 shown in FIG. 4 and the like.

The delay circuit D10 determines a timing of activating the write column selection line bWCSL.

Accordingly, the write column selection line bWCSL corresponding to a column designated by a column address can be activated at a predetermined timing during the data write operation based on the write enable signal WE, the column decoder signal CDCn, and the delay circuit D10.

1. A semiconductor memory device comprising:
a plurality of memory cells comprising bodies in electrically floating states, and configured to store data according to number of carriers in the bodies;
a word line connected to gates of the memory cells;
a first bit line and a second bit line configured to transmit data to the memory cells or to transmit the data from the memory cells;
a first sense node connected to the first bit line and a second sense node connected to the second bit line;
a latch circuit configured to latch the data from the first bit line to the first sense node, and to latch the data from the second bit line to the second sense node;
a first data line configured to read out the data latched to the first sense node to an outside or to transmit data from the outside to the first sense node;
a second data line configured to read out the data latched to the second sense node to the outside or to transmit the data from the outside to the second sense node;
a first write transistor directly connected between the first bit line and either the first data line or the second data line without via the first sense node and the second sense node; and
a second write transistor directly connected between the second bit line and either the first data line or the second data line without via the first sense node and the second sense node, wherein
the first write transistor is configured to transmit the data from the first data line or the second data line to the first bit line, or the second write transistor is configured to transmit the data from the first data line or the second data line to the second bit line, in a data write operation.

2. The device of claim 1, wherein the first write transistor is configured to connect the first bit line to the second data line and the second write transistor is configured to connect the second bit line to the first data line, in the data write operation, while or immediately after a sense amplifier comprising the first sense node, the second sense node and the latch circuit is detecting the data in one of the memory cells.

3. The device of claim 1, wherein the first write transistor is configured to connect the first bit line to the first data line and the second write transistor is configured to connect the second bit line to the second data line, in the data write operation, when a sense amplifier comprising the first sense node, the second sense node and the latch circuit starts detecting the data in one of the memory cells.

4. The device of claim 1, further comprising a feedback circuit configured to transmit the data latched to the first sense node and transmitted from the first data line to the second bit line and to transmit the data latched to the second sense node and transmitted from the second data line to the first bit line, wherein
the feedback circuit is configured to transmit the data from the first data line to the second bit line or to the first bit line and transmits the data from the second data line to the first bit line or the second bit line in the data write operation, after the first write transistor and the second write transistor become conductive.

5. The device of claim 2, further comprising a feedback circuit configured to transmit the data latched to the first sense node and transmitted from the first data line to the second bit line and to transmit the data latched to the second sense node and transmitted from the second data line to the first bit line, wherein
the feedback circuit is configured to transmit the data from the first data line to the second bit line or to the first bit line and to transmit the data from the second data line to the first bit line or the second bit line in the data write operation, after the first write transistor and the second write transistor become conductive.

6. The device of claim 3, further comprising a feedback circuit configured to transmit the data latched to the first sense node and transmitted from the first data line to the first bit line and to transmit the data latched to the second sense node and transmitted from the second data line to the second bit line, wherein
the feedback circuit is configured to transmit the data from the first data line to the second bit line or to the first bit line and to transmit the data from the second data line to the first bit line or the second bit line in the data write operation, after the first write transistor and the second write transistor become conductive.

7. The device of claim 1, wherein each of the first write transistor and the second write transistor comprises a positive (P)-type field effect transistor (FET).

8. The device of claim 1, wherein each of the first write transistor and the second write transistor comprises a P-type FET and a negative (N)-type FET connected in parallel.

9. The device of claim 1, wherein each of the first write transistor and the second write transistor comprises a N-type FET.

10. The device of claim 1, further comprising:
a plurality of transfer gates connected between the first bit line and the first sense node and between the second bit line and the second sense node, wherein
a write control line connected to gates of the first write transistor and the second write transistor, and configured to make the first write transistor and the second write transistor conductive when the data write operation starts or when the transfer gate closes.

11. The device of claim 5, further comprising:
a plurality of transfer gates connected between the first bit line and the first sense node and between the second bit line and the second sense node, wherein
a write control line connected to gates of the first write transistor and the second write transistor, and configured to make the first write transistor and the second write transistor conductive when the data write operation starts or when the transfer gate closes.

12. The device of claim 6, further comprising:
a plurality of transfer gates connected between the first bit line and the first sense node and between the second bit line and the second sense node, wherein
a write control line connected to gates of the first write transistor and the second write transistor, and configured to make the first write transistor and the second write transistor conductive when the data write operation starts or when the transfer gate closes.

13. The device of claim 7, further comprising:
a plurality of transfer gates connected between the first bit line and the first sense node and between the second bit line and the second sense node, wherein
a write control line connected to gates of the first write transistor and the second write transistor, and configured to make the first write transistor and the second write transistor conductive substantially simultaneously with start of the data write operation or when the transfer gate closes.

14. The device of claim 1, further comprising a plurality of transfer gates connected between the first bit line and the first sense node and between the second bit line and the second sense node, wherein
the transfer gates become conductive substantially simultaneously with or immediately after start of the data write operation.

15. The device of claim 2, further comprising a plurality of transfer gates connected between the first bit line and the first sense node and between the second bit line and the second sense node, wherein
the transfer gates become conductive substantially simultaneously with or immediately after start of the data write operation.

16. The device of claim 3, further comprising a plurality of transfer gates connected between the first bit line and the first sense node and between the second bit line and the second sense node, wherein
the transfer gates become conductive substantially simultaneously with or immediately after start of the data write operation.

17. The device of claim 4, further comprising a plurality of transfer gates connected between the first bit line and the first sense node and between the second bit line and the second sense node, wherein
the transfer gates become conductive substantially simultaneously with or immediately after start of the data write operation.

18. The device of claim 7, further comprising a plurality of transfer gates connected between the first bit line and the first sense node and between the second bit line and the second sense node, wherein
the transfer gates become conductive substantially simultaneously with or immediately after start of the data write operation.

19. A method of driving a semiconductor memory device comprising a plurality of memory cells configured to store data; a word line connected to gates of the memory cells; a first bit line and a second bit line configured to transmit the data from the memory cells; a first sense node corresponding to the first bit line and a second sense node corresponding to the second bit line; a first data line corresponding to the first sense node and a second data line corresponding to the second sense node; a first write transistor between the first bit line and the first data line or the second data line; and a second write transistor between the second bit line and the first data line or the second data line, the method comprising:
causing the first write transistor to transmit data from the first data line or the second data line to the first bit line, or causing the second write transistor to transmit the data from the first data line or the second data line to the second bit line, in a data write operation.
